(19) United States
(12) Patent Application Publication
(10) Pub. No.: US 2009/0068596 A1
(43) Pub. Date: Mar. 12, 2009

(54) Negative-tone,Ultraviolet Photoresists for Fabricating High Aspect Ratio Microstructures

(76) Inventors: Ren Yang, Corona, CA (US); Steven A. Soper, Baton Rouge, LA (US); Wanjun Wang, Baton Rouge, LA (US)

Correspondence Address: PATENT DEPARTMENT;TAYLOR, PORTER, BROOKS & PHILLIPS, L.L.P, P.O. BOX 2471, BATON ROUGE, LA, 70821-2471, US

(21) Appl. No.: 12/185,455

(22) Filed: Aug. 4, 2008

Related U.S. Application Data
(60) Provisional application No. 60/954,195, filed on Aug. 6, 2007.

(51) Int. Cl. G03F 7/20; C08F 2/46; B32B 37/12

(52) U.S. Cl. 430/296; 430/325; 522/1; 156/275.5

(57) ABSTRACT

UV photoresist materials are disclosed, based on EPON 154 or EPON 165. Preferred embodiments, based on a composite of EPON 154 and EPON 165, spread evenly into a flat, uniform layer, even without spin-coating. The preferred embodiments bond strongly to all substrates, and are resistant to cracking and debonding following exposure and development. The preferred embodiments have high UV transmittance, which promotes uniform photopolymerization throughout a thick layer. Structures may be produced by UV lithography that have a sidewall quality that has previously been attainable only by photolithography with a collimated x-ray source.

The benefit of the Aug. 6, 2007 filing date of provisional patent application 60/954,195 is claimed under 35 U.S.C. § 119(e).

The development of this invention was partially funded by the Government under grant numbers ECS-0524626 and EPS-0346411 awarded by the National Science Foundation. The United States Government has certain rights in this invention.

### TECHNICAL FIELD

This invention pertains to photoresists, particularly to negative-tone, ultraviolet photoresists that are well-suited for fabricating high aspect ratio microstructures.

### BACKGROUND ART

Photoresists are polymeric or monomeric coatings whose properties change upon exposure to x-rays, ultraviolet radiation (UV), or visible light. Photoresists are commonly used: (1) to create patterned “resists” that, in turn, protect selected portions of a substrate from subsequent processing such as chemical etching, ion implantation, or metal deposition; or (2) to fashion micro electromechanical systems (MEMS) directly from the photoresist layer itself. For surface-patterning applications, thin films (˜1 μm) are usually preferred for high resolution and for ease in post-processing photoresist removal, while for MEMS applications thick (˜100 μm), or even “ultra-thick” (>1,000 μm) photoresist films are usually preferred.

Photoresists are typically deposited onto a flat substrate as a viscous liquid mixture by spin-coating. The spin-coating is followed by “soft-baking” (or “pre-baking”), a low-temperature heating that removes solvent from the coating mixture. The photoresist coating is then irradiated with actinic light (x-ray, UV, or visible) through a stencil, or mask, imparting the mask pattern to the photoresist.

The impinging radiation causes chemical changes in the exposed regions of the photoresist film. Depending on the composition of the particular photoresist used, it is possible to selectively wash away either the exposed regions or the unexposed photoresist regions, using a fluid called the “developer.” When the exposed region of the photoresist becomes more soluble and is removed by the developer, the photoresist is “positive-tone”. Conversely, “negative-tone” photoresists remain on the substrate because the irradiation makes them less soluble in the developer.

Developing is usually followed by “hard-baking,” a high temperature bake that thermally polymerizes the photoresist further and improves adhesion to the substrate.

In surface-patterning applications the exposed substrate is then typically modified by processes such as chemical etching, ion implantation, and metal deposition. During the modification step, the unremoved photoresist protects the underlying substrate from the effects of the modification. Following this differential processing, a “stripping” reagent removes the remaining protective photoresist. To create complex semiconductor chips or complex microdevices, the spin coat deposition/soft bake/exposure/development/hard bake/substrate processing/stripping cycle may be repeated several times.

In its simplest form MEMS photolithography comprises the deposition, soft-bake, photoexposure, developing, and hard-bake steps, with an optional step of removing the fabricated MEMS from the substrate.

The UV photoresist SU-8 and the X-ray photoresist poly(methylmethacrylate) (PMMA) are widely used in fabricating high-aspect-ratio MEMS. X-ray lithography of PMMA can produce high-aspect-ratio microstructures with extremely high quality sidewalls, smooth and perpendicular to the substrate surface. However, x-ray lithography typically requires a synchrotron light source, which is often unavailable or too costly.

SU-8 and its use as a negative photoresist for making MEMS is disclosed in numerous publications, including for example H. Lorenz et al., “SU-8: a low-cost negative resist for MEMS,” J. Micromech. Microeng., vol. 7, pp. 121-124 (1997); H. Lorenz et al., “High-aspect-ratio, ultrathick, negative-tone near-UV photoresist and its applications for MEMS,” Sensors and Actuators A, vol. 64, pp. 33-39 (1998)

At a lower resolution than may be achieved by x-ray lithography of PMMA, SU-8 can be polymerized by UV radiation. Collimated UV sources are substantially less expensive than collimated x-ray sources. SU-8 has reasonably good lithographic properties, but it also has disadvantages. The spin-coating properties are not particularly good, for either thick or thin layers of SU-8. Indeed, the flatness error for a 1,000 μm-thick SU-8 photoresist film may exceed 100 μm over the area of a standard semiconductor wafer. Such irregularities can cause diffraction and refraction errors that lead to non-uniform photopolymerization.

Another disadvantage of SU-8 is its susceptibility to debonding, the undesired separation of portions of the photoresist from the substrate. Debonding typically occurs during or after baking and developing. For some commonly used substrates, such as glass, photoresist adhesion and debonding are challenging issues. Some microstructure features, such as long lines, tend to be particularly susceptible to debonding, which imposes undesirable design limitations upon some MEMS structures. A further disadvantage of SU-8 is that cracks and fissures can appear in the photoresist after baking, particularly at corners. Cracking and de-bonding may both result from residual stresses, induced by a several-percent decrease in volume as the SU-8 cures. The bottom of the microstructure is bonded to the substrate and cannot shrink with the upper portion. Internal stresses result, manifesting most readily at corners. The stress increases disproportionately with increasing film thickness, because SU-8 is not transparent to the polymerizing UV radiation, which leads to substantial attenuation at increasing depths. The attenuation, in turn, leads to a lower degree of polymerization in lower strata of the film; and the uneven polymerization leads to increased internal stresses, cracking, and de-bonding.

An unfilled need exists for a UV-sensitive photoresist material that can readily be deposited evenly and flatly upon common substrates. Such a material should have low susceptibility to de-bonding and cracking, and it should have a high transmittance for actinic UV radiation, so thick films will polymerize evenly.

EPON 154 is an epoxy resin manufactured from phenolic novolac resin and epichlorohydrin. Its use has been reported in a number of industrial, electrical, and chemical applications. However, to the knowledge of the inventors, there are no prior reports of using it as a photoresist. It has been used in chemical-resistant tank linings, flooring and grouts, electrical laminates and encapsulation, casting and molding compounds, construction and electrical adhesives. The chemical structure of EPON 154 is shown in FIG. 1. Uncured EPON 154 is semi-solid at room temperature, but when reacted with chemical curing agents, it forms highly cross-linked solid compositions exhibiting high chemical resistance, high temperature resistance, and high dimensional stability. EPON 154 has a thermal cross-linking temperature between 130° C. and 140° C. The equivalent molecular weight is 176-181 g/eq, its viscosity is 5-12 Poise at 25° C., and its density is 10.2 lbs/gal. EPON 154 is available commercially from Hexion Specialty Chemicals, Inc., Columbus, Ohio 43215. See generally EPON™ Resin 154 Product Bulletin (Resolution Performance Products, January 2004); EPON™ Resin 154 Material Safety Data Sheet, Version 1 (Resolution Performance Products, Print Date Feb. 3, 2004); EPON Resins and Modifiers, p. 12 (Hexion Specialty Chemicals 2005); and Physical Properties Guide for Epoxy Resins and Related Products, p. 10 (Resolution Performance Products 2001).

EPON 165 is an amber, solid, multifunctional cresol novolac epoxy resin. Its use has been reported in a number of industrial, electrical, and chemical applications. However, to the knowledge of the inventors, there are no prior reports of using it as a photoresist. Its melting temperature is 91° C. and its density is 10 lbs/gal. As shown in FIG. 3, EPON 165 has an average of 5 to 6 epoxide groups per molecule of monomer. The high functionality of EPON 165 leads to short cure times and facilitates handling and speed of production. EPON 165 generally imparts a high glass transition temperature and cross-link density to cured products, which in turn imparts good strength, rigidity, electrical, and other properties at elevated temperatures. The resin has strong adhesive properties for bonding both metal and non-metal structural components. EPON 165 is easily ground into uniform particle size, and easily blended with other epoxy resins. Its low melt viscosity provides ease of handling and good flow characteristics. EPON 165 is available commercially from Hexion Specialty Chemicals, Inc., Columbus, Ohio 43215. See generally EPON™ Resin 164/EPON Resin 165* Technical Data Sheet (Hexion Specialty Chemicals 2005); EPON™ Resin 165 Material Safety Data Sheet, Version 7 (Resolution, Print Date Dec. 9, 2004); EPON Resins and Modifiers, p. 12 (Hexion Specialty Chemicals 2005); and Physical Properties Guide for Epoxy Resins and Related Products, p. 10 (Resolution Performance Products 2001).

See also a paper by the present inventors, R. Yang et al., “A New UV Lithography Photoresist Based on Composite of EPON Resins 165 and 154 for Fabrication of High-Aspect-Ratio Microstructures,” Sensors and Actuators A, vol. 135 pp. 625-636 (2007; available online Oct. 18, 2006).

### SUMMARY OF THE INVENTION

We have discovered novel UV photoresist materials that fulfill the unmet needs described above. Preferred embodiments spread so easily and so evenly that merely pouring them upon the substrate often suffices to make a flat, uniform layer, without the need for spin-coating or the like. Unlike SU-8, the preferred embodiments bond strongly to all substrates that are in common use today for manufacturing microstructures. Even ultrathick films (>˜1000 μm) of the preferred embodiment exhibit no substantial cracking or debonding from commonly-used substrates during deposition, soft-baking, photoexposure, developing, or hard-baking. Furthermore, the preferred embodiments have a high transmittance at the actinic UV wavelengths, which promotes uniform top-to-bottom film photopolymerization. Internal stresses are greatly reduced in the preferred embodiments, as compared to those in structures made from prior UV photoresists such as SU-8.

We have discovered that EPON 154, not previously reported to be a photoresist, may be used as an ultraviolet, negative-tone photoresist. We have also discovered that EPON 165, not previously reported to be a photoresist, may be used as an ultraviolet, negative-tone photoresist. We have further discovered that mixtures of EPON 154 and EPON 165 have particularly good properties as ultraviolet photoresists.

Preferred embodiments of ˜1:1 EPON 154/EPON 165 composites offer several advantages as UV photoresists: 1) The spreadability and wetting properties allow much smoother films to be spread upon substrates, with or without spin-coating. 2) The exposed, developed photoresists are resistant to de-bonding from the substrate, allowing previously unattainable long, fine lines to be photolithographed. 3) The exposed, developed photoresists exhibit few or no cracks and fissures. 4) The composition is more UV-transparent than conventional photoresists, allowing uniform polymerization throughout the depth of the photoresist film. 5) Using UV radiation, structures may be produced with a sidewall quality previously attainable only by photolithography with a collimated x-ray source. 6) With the preferred EPON 154/EPON 165-based photoresists, “T-topping” has not been observed, the bulbous distortion of sidewall tops, often seen in ultra-thick SU-8 UV lithography. 7) Microstructures with aspect-ratios greater than 100 can be prepared by ultraviolet lithography in thick (>1 mm) photoresist films. We have successfully produced microstructures with heights over 1000 μm, 10 μm feature sizes, and excellent sidewall quality with the novel composite photoresist.

The novel photoresist material comprises a resin, a photoinitiator, and a solvent. The resin component comprises EPON 154, EPON 165, or preferably a mixture of both EPON 154 and EPON 165. The photoinitiator may be selected from those known in the art, and is preferably a triaryl sulfonium salt, for example Cyracure UVI 6970 from Dow Chemical. The solvent may be selected from those known in the art, and is preferably gamma-butyrolactone (GBL). Optionally, additional components may also be incorporated into the photoresist to modify the properties of the photoresist material or its processing, for example liquid epoxy resins such as EPON 828 or EPON 862. It is preferred that any optional components not absorb strongly in the near UV range, as the mixture otherwise exhibits very high optical transmission in the near UV, which allows the fabrication of ultra-thick photoresist layers that may be exposed nearly uniformly throughout their thickness.

For most purposes, neither EPON 154 alone nor EPON 165 alone provides an optimal photoresist for microstructure fabrication. EPON 154, for example, is a semi-solid at room temperature, which makes it less desirable as a photoresist; nevertheless, its lithography properties are excellent, and a semi-solid resist can be used in non-contact lithographic techniques. Because EPON 165 has a high cross-linking density, it tends to produce structures with high internal stresses that lead to cracking and de-bonding. We have discovered that a mixture of the two provides surprisingly improved properties, combining the advantages of both and minimizing the disadvantages of each. Without wishing to be bound by this hypothesis, we expect that the EPON 154 units and the EPON 165 units will, at least to some extent, cross-link to one another when photopolymerization occurs, rather than remaining entirely distinct domains.

Alternatively, the new material may be used as an x-ray photoresist, in thin, thick, or ultra-thick layers.

The preferred mass ratio of EPON 154 to EPON 165 varies from about 1:5 to about 5:1, with a more preferred ratio of about 1:1. The two resins are mixed in the chosen ratio and dissolved in solvent. In general, little or no chemical reaction between the components occurs at this point; the mixing process is primarily or entirely a physical mixing only. The solution is photosensitized by adding photoinitiator, which is preferably done after the resins have been mixed and dissolved in the solvent.

The preferred mixture, a composite of EPON 154 and EPON 165, produces a negative-tone UV photoresist with unexpected properties that are particularly well-suited for fabricating ultra-high-aspect-ratio microstructures. In prototype embodiments we have produced microstructures with heights of more than 1,000 μm and in-plane resolution of 10 μm (i.e., aspect ratios greater than 100). The resulting microstructures have excellent sidewall quality. The photoresist surfaces fabricated from the novel material are flat, do not appear to crack to any appreciable extent, and show little or no tendency to de-bond.

### BRIEF DESCRIPTION OF THE DRAWINGS

FIG. 1 depicts the chemical structure of EPON 154.

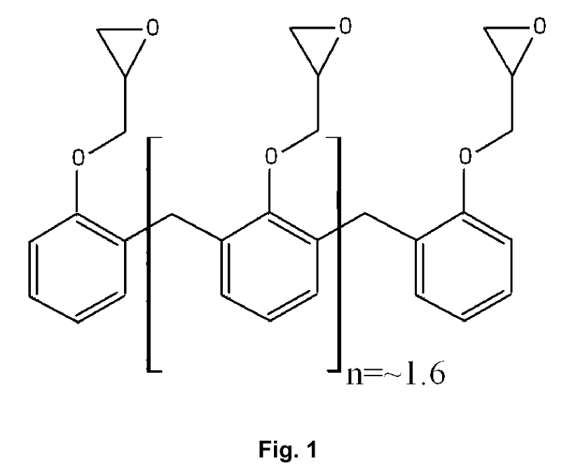

FIG. 2 depicts transmission as a function of UV wavelength for an EPON 154-based photoresist film.

FIG. 3 depicts the chemical structure of EPON 165.

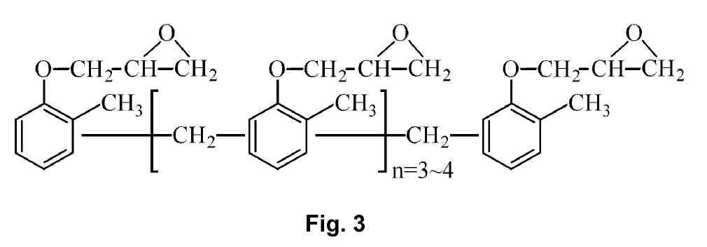

FIG. 4 depicts transmission as a function of UV wavelength for a 108.4 μm thick EPON 165 film.

FIGS. 5(A) and 5(B) depict, respectively, UV transmission spectra for several unexposed photoresists and the corresponding exposed photoresists.

FIGS. 6(A) and 6(B) depict UV transmission spectra of unexposed and exposed 1:1 EPON 154/EPON 165 composite photoresists, respectively.

FIGS. 7(A) and 7(B) depict the index of refraction and extinction coefficient as a function of wavelength for, respectively, the unexposed and the exposed and developed 1:1 EPON 154/EPON 165 composite photoresist.

FIG. 8 depicts a spin-coating curve for a 1:1 EPON 154/EPON 165 solution.

FIG. 9 depicts preferred pre-exposure bake times as a function of film thickness for the 1:1 EPON 154/EPON 165 composite photoresist.

FIGS. 10(A) and 10(B) depict, respectively, recommended exposure as a function of thickness for a 60:40 EPON 154/EPON 165 composite photoresist for a broadband UV source, and for an h-line dominated light source.

FIGS. 11(A), (B), and (C) depict surface flatness measurements for, respectively: a 1:1 EPON 154/EPON 165 composite photoresist, an SU-8 2100 photoresist, and an SU-8 100 photoresist.

### MODES FOR CARRYING OUT THE INVENTION

### Physical, Lithographic and Spectroscopic Properties of EPON 154-based Photoresists

### EXAMPLE 1

### An EPON 154-based Photoresist

EPON 154 was dissolved in GBL in a mass ratio of 85% EPON 154 to 15% GBL. A photoinitiator, Cyracure UVI 6970, was then added to the solution in a mass ratio of 1:16.15, and the solution was thoroughly mixed. The resulting photoresist, after removal of solvent, was a semi-solid at room temperature. The solution was used to make the photoresist for Examples 2 and 3 below.

### EXAMPLE 2

### UV Transmission Spectra of EPON 154-based Photoresist

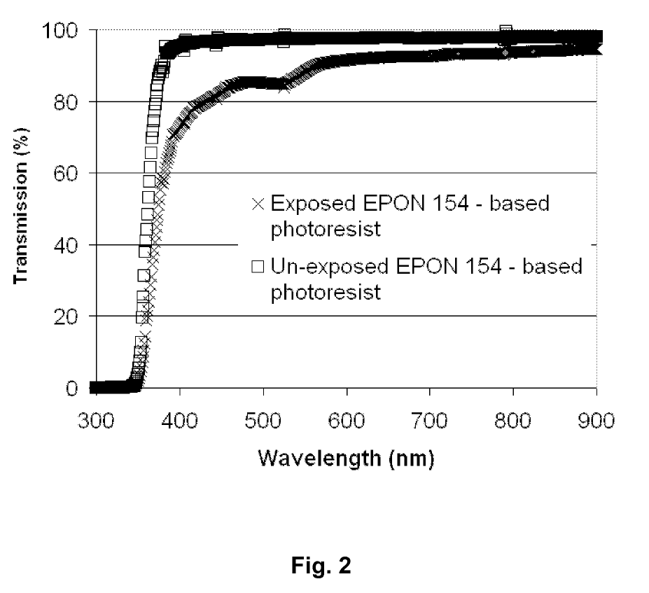

The EPON 154-based photoresist had a very high transmission in the near-UV. The transmission spectra of exposed and unexposed 152.8 μm-thick EPON 154-based photoresists are shown in FIGS. 2(A) and (B), respectively. For the unexposed film, transmission was 61.61% at 365 nm and 95.17% at 405 nm. After UV curing, the cross-linked EPON 154 polymer still demonstrated excellent transmission properties at wavelengths longer than 600 nm. As compared to SU-8, the unexposed EPON 154 photoresist showed similar absorption at wavelengths shorter than 400 nm, but had substantially lower absorption at wavelengths longer than 400 nm. The attenuation coefficients for unexposed SU-8 were 0.003 μm⁻¹ at 365 nm and 0.0005 μm⁻¹ at 405 nm; while those for the unexposed EPON 154-based photoresists were 0.003 μm⁻¹ at 365 nm and 0.0003 μm⁻¹ at 405 nm. The UV transmission of cured SU-8 decreases as the wavelength increases to 900 nm and longer wavelengths, while the UV transmission of cured EPON 154 polymer does not depend as strongly on wavelength over this range.

### EXAMPLE 3

### Lithographic Properties of EPON 154-based Photoresist

Because EPON 154 is a semi-solid at room temperature, a photoresist based solely on EPON 154 may adhere to photomasks in a contact lithography process. An EPON 154 (only) photoresist should therefore only be used in projection lithography, not contact lithography, unless special measures are taken. For example, a thin glycerin separation layer may be applied between the photoresist and the mask as described in step (3) below. The use of a glycerin separation layer is common in SU-8 lithography for air gap compensation. Because glycerin has a refractive index of 1.472 at 20° C., reasonably close to that of the EPON 154-based photoresist, glycerin may be used both for air gap compensation and as a separation layer between the EPON 154 and the mask to overcome adhesion problems. Step (3) may be omitted for non-contact lithography. A typical lithography processing procedure for the EPON 154-based photoresist was as follows:

1) A silicon wafer surface was cleaned, using techniques known in the art.
2) The wafer was spin-coated with the EPON 154/photoinitiator/GBL solution at 500 rpm for 25 seconds, and soft-baked at 96° C. for 3.5 hours. (Spin-coating is optional, depending on the precise composition of the particular photoresist, but is nevertheless preferred in many circumstances to improve flatness.)
3) A small amount of glycerin was dropped onto the central area of the photoresist to form a thin film between the photomask and the EPON 154 layer.
4) The EPON 154 layer was exposed to a broadband UV light source at ˜1,000 mJ/cm².
5) The mask was separated from the exposed EPON 154 layer in de-ionized (DI) water, and blow-dried using nitrogen gas.
6) The assembly was hard-baked for 10 minutes at 90° C.
7) The assembly was developed in propylene glycol methyl ether acetate (PGMEA) for about 0.5 hour.
8) The assembly was rinsed with fresh PGMEA developer, followed by a rinse in isopropyl alcohol (IPA) for 3 minutes, followed by a final rinse with DI water, and air drying.

### Physical, Lithographic and Spectroscopic Properties of EPON 165-based Photoresists

### EXAMPLE 4

### An EPON 165-based Photoresist

EPON 165 was dissolved in GBL at a mass ratio of 34% GBL to 66% EPON 165. A photoinitiator, Cyracure UVI 6970, was then added to the solution in a mass ratio of 1:16.15, and the solution was thoroughly mixed. The resulting photoresist, after removal of solvent, was a solid at room temperature. The solution was used to make the photoresist for Examples 5 and 6 below.

### EXAMPLE 5

### UV Transmission Spectra of EPON 165-based Photoresists

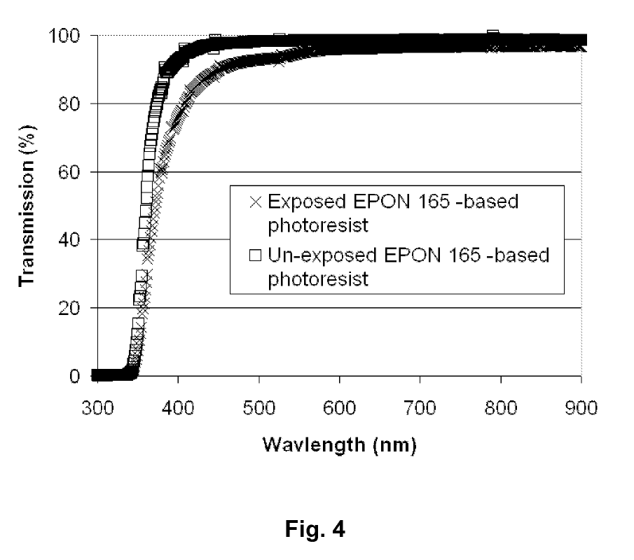

The resulting solution was a negative-tone UV photoresist with lithographic properties similar in many ways to those of SU-8. Unlike SU-8, this formulation possessed desirable high UV transmission. FIG. 4 depicts transmission versus wavelength for a 108.4 μm EPON 165-based photoresist film. For the unexposed film, transmission was 65.08% at 365 nm and 93.02% at 405 nm.

### EXAMPLE 6

### Lithographic Processing of EPON 165-based Photoresists

A typical lithography processing procedure for the EPON 165-based photoresist was as follows:

1) A silicon wafer surface was cleaned using techniques known in the art.
2) The wafer was spin-coated with the EPON 165/photoinitiator/GBL solution at 400 rpm for 25 seconds to obtain a 350 μm thick photoresist film.
3) The assembly was pre-baked at 96° C. for 6 hours.
4) The assembly was subjected to contact lithography at an exposure dosage of 1,200 mJ/cm² using a broadband light source, or 12,000 mJ/cm² for an h-line dominated light source.
5) The assembly was hard-baked for 10 minutes at 90° C.
6) The assembly was developed in propylene glycol methyl ether acetate (PGMEA) for about 50 minutes.
7) The assembly was rinsed with fresh PGMEA developer, followed by rinsing in isopropyl alcohol (IPA) for 3 minutes, followed by a final rinse with Di water once the IPA no longer became milky during rinsing (indicating the conclusion of development), and followed by air drying.

Prototype EPON 165-based photoresists produced microstructures of the same quality as, but with a much shorter curing time than those made of SU-8. Unlike EPON 154-based photoresists, EPON 165-based photoresists were solid at room temperature after pre-baking, obviating the photoresist/mask adhesion problems encountered in contact lithography with EPON 154-based photoresists and SU-8 photoresists. This advantage is significant, considering that most MEMS fabrication facilities use contact lithography.

However, there are several disadvantages of photoresists based on EPON 165 (only), as compared to the EPON 154 (only)-based photoresists. First, the EPON 165-based photoresist has a higher cross-linking density, which produces a greater potential for internal stresses. Second, even a small exposure difference between the top and bottom layers of the photoresist may cause substantial differences in curing due to the much higher cross-linking density; these differences can affect the sidewall profile of the microstructures. Third, its development is slower. It is more difficult to remove unpolymerized EPON 165-based photoresist as compared to either SU-8 photoresists or to EPON 154 (only)-based photoresists. Also, because EPON 165 has a higher molecular weight than either EPON 154 or SU-8, more solvent is needed to dissolve the same amount of resin.

### Physical, Lithographic and Spectroscopic Properties of EPON 154/EPON 165-based Photoresists

The EPON 165-based photoresist and the EPON 154-based photoresist each present advantages and disadvantages. Because EPON 154 has excellent flexibility and mobilization, EPON 154-based photoresists have excellent surface flatness and adhesion; and the high cross-linking density gives them a fast cross-linking rate (curing rate). However, EPON 154 is semi-solid at room temperature after pre-baking, which makes it difficult to use in contact mode during UV exposure. By contrast, EPON 165-based photoresists do not have photomask adhesion problems, but their surface flatness error is no better than that of SU-8 photoresists. Either EPON 154 alone or EPON 165 alone may be used to advantage in composite photoresist mixtures with other materials. However, we have found especially good properties from photoresists made of composites containing both EPON 154 and EPON 165.

### EXAMPLE 7

### Photoresists Comprising Mixtures of EPON 154 and EPON 165

We prepared photoresists comprising a mixture of EPON 154 and EPON 165 by procedures that generally followed those described in the previous examples. After the two resins were mixed in the desired ratio, they were dissolved in gamma-butyrolactone (GBL). The solution was then photosensitized by adding the Cyracure UVI 6970 photoinitiator.

We found that when EPON 165 comprises more than about 40% of the mixture by mass of an EPON 165/EPON154 mixture, the resulting photoresist is solid at room temperature after post-baking, and there is then no photomask adhesion problem in contact lithography under reasonable levels of pressure.

### EXAMPLE 8

### Optical Properties of EPON 154/EPON 165-based Photoresists

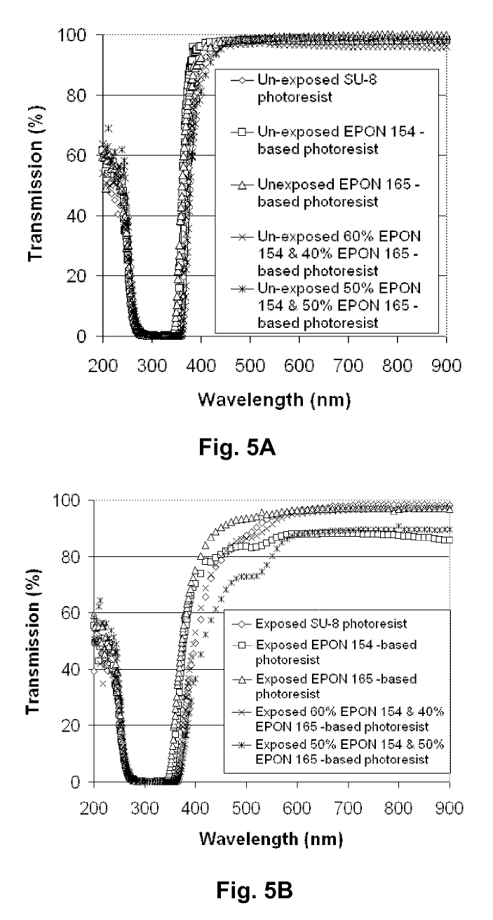

We measured UV absorbance for unexposed and exposed photoresists based on EPON 154 (only), or EPON 165 (only), or several ratios of EPON 154/EPON 165 mixtures. All displayed the desired high UV transmission. FIG. 5A depicts transmission data for unexposed photoresist films; and FIG. 5B depicts transmission data for the corresponding exposed and developed photoresist films: (a) 493.6 μm-thick, 40:60 EPON 154/EPON 165-based film, (b) 768.7 μm-thick, 50:50 ratio EPON 154/EPON 165-based film, (c) 152.8 μm-thick EPON 154-resist based film, (d) 108.4 μm-thick EPON 165-based film; and (e) 396.8 μm-thick SU-8 film.

As shown in FIG. 5A, the unexposed photoresists based on mixtures of EPON 165 and EPON 154 had high transmission in the near UV. For a 493.6 μm thick unexposed photoresist film with a 40:60 EPON 154/EPON 165 mixture, UV transmission was about 22.70% at 365 nm and 87.43% at 405 nm. In another experiment, a 50:50 composite, unexposed photoresist, 540 μm thick showed UV transmission of about 25.01% at 365 nm and 85.23% at 405 nm.

The high transmission of unexposed photoresist means that the polymerizing radiation penetrates very thick photoresist layers without significant attenuation; which makes these photoresists well adapted for the fabrication of high aspect ratio microstructures.

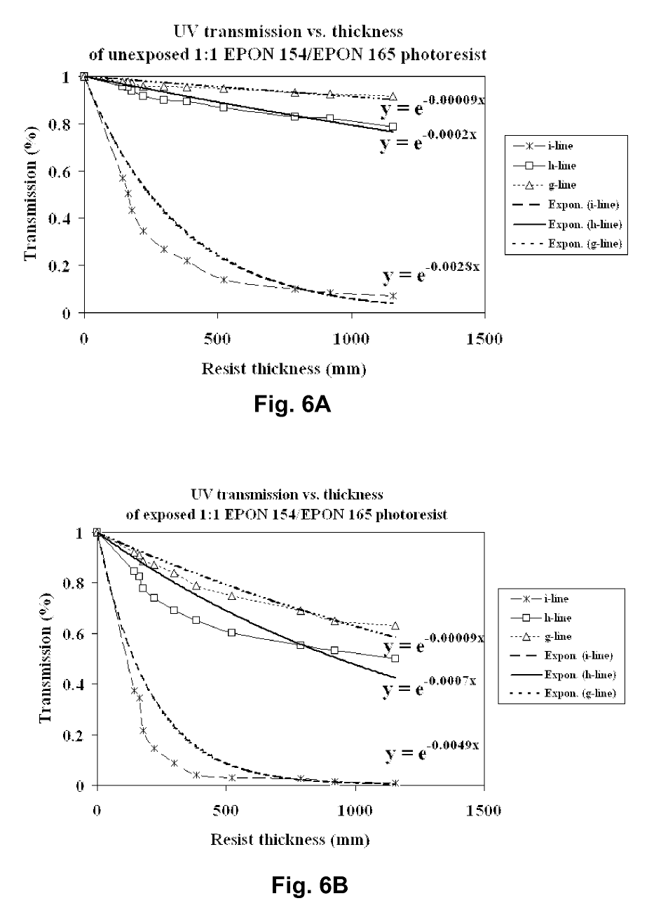

FIG. 6 depicts absorption coefficients at several wavelengths for unexposed photoresists, based on measurements with a 50:50 EPON 154/EPON 165 mixture for different film thicknesses. The absorption coefficient for the unexposed photoresist film was found to be 0.0028 for the i-line (˜365 nm), 0.0002 for the h-line (˜405 nm), and 0.00009 for the g-line (˜436 nm) of a mercury vapor lamp.

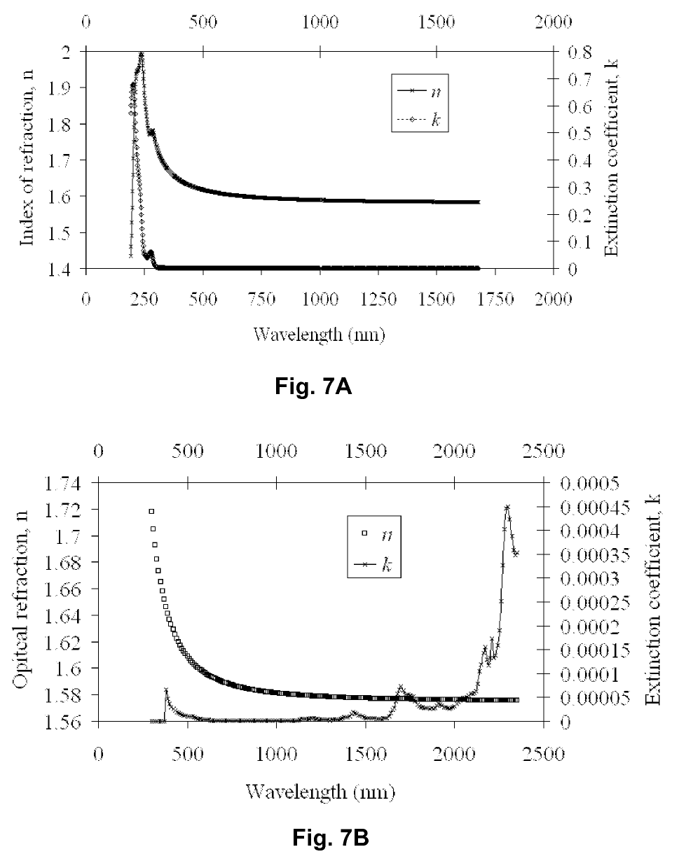

FIGS. 7(A) and 7(B) depict indices of refraction and extinction coefficients for the 50:50 EPON 154/EPON 165 photoresist. These measurements were taken with a M-2000 spectroscopic ellipsometer (J.A. Woollam Co., Lincoln, Neb.). FIGS. 7(A) and 7(B) depict the measured refractive index and extinction coefficients as a function of wavelength for the unexposed and exposed photoresist films, respectively.

### EXAMPLE 9

### Viscosity of EPON 154/EPON 165-based Photoresists

EPON 154 and EPON 165 are both highly soluble in many organic solvents (often up to ˜80% of the total solution by mass). Solutions with higher concentrations tend to be more viscous. Viscosity is a desirable feature when making thick and ultra-thick photoresist layers, for fabricating high-aspect-ratio and ultra-high-aspect-ratio microstructures.

### EXAMPLE 10

### Cross-linking & Curing of EPON 154/EPON 165-based Photoresists

The 50:50 EPON 154/EPON 165 photoresist was analyzed with a TA DSC thermal analyzer. The photoresist started to cross-link thermally at ˜140° C., without any UV exposure. The glass transition temperature of the cured 50:50 EPON 154/EPON 165 photoresist was ˜130° C. By contrast, the glass transition temperature of cured SU-8 is above ˜220° C.

### EXAMPLE 11

### Spin-Coating, Soft-Baking, and Curing of EPON 154/EPON 165-based Photoresists

A preferred range for good processability of the composite photoresist is a mass ratio of EPON 154 to EPON 165 between about 40:60 and about 50:50. A preferred mass ratio of the total photoresist mixture to the preferred GBL solvent is about 85:15. A photoinitiator, e.g., Cyracure UVI 6970, may then be added to the solution at a preferred mass ratio of ˜5%.

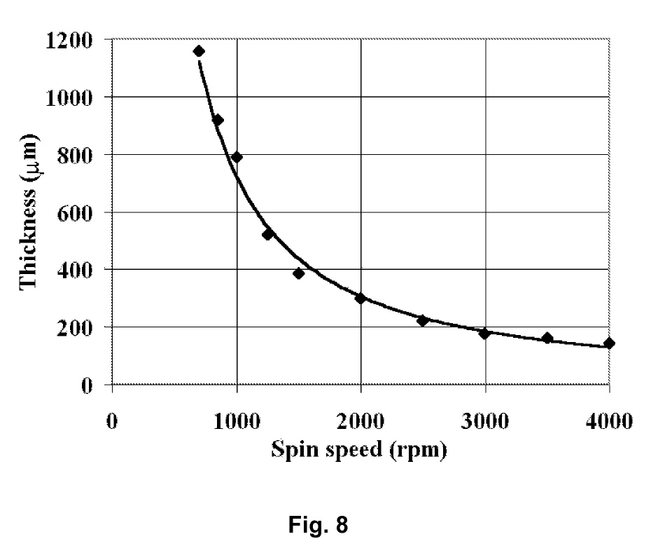

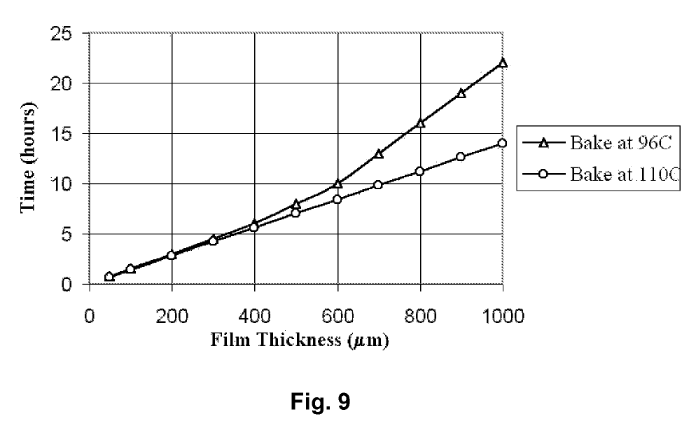

A film thickness up to about 1,000-1,500 μm or even thicker can be achieved with a single spin-coating step. Although reasonable flatness can be obtained simply by pouring the resist onto a substrate and baking, a spin-coating step is nevertheless preferred for optimal flatness. The photoresist was typically soft-baked on a hotplate for 14 hours at 110° C. Lithography was carried out with a broadband UV light source containing the i-, h-, and g-lines. It is preferred that the soft-bake temperature should be lower than about 125° C., because the photoresist thermally cures ˜140° C., and it can begin to thermally cure (albeit at a slower rate) even below ˜140° C. FIG. 8 depicts measured values for thickness as a function of the spin-coating rotational velocity for a 1:1 EPON 154/EPON 165 composite photoresist. FIG. 9 depicts recommended times for soft-baking at different temperatures for this composite photoresist, as a function of thickness.

### EXAMPLE 12

### UV Exposure of EPON 154/EPON 165-based Photoresists

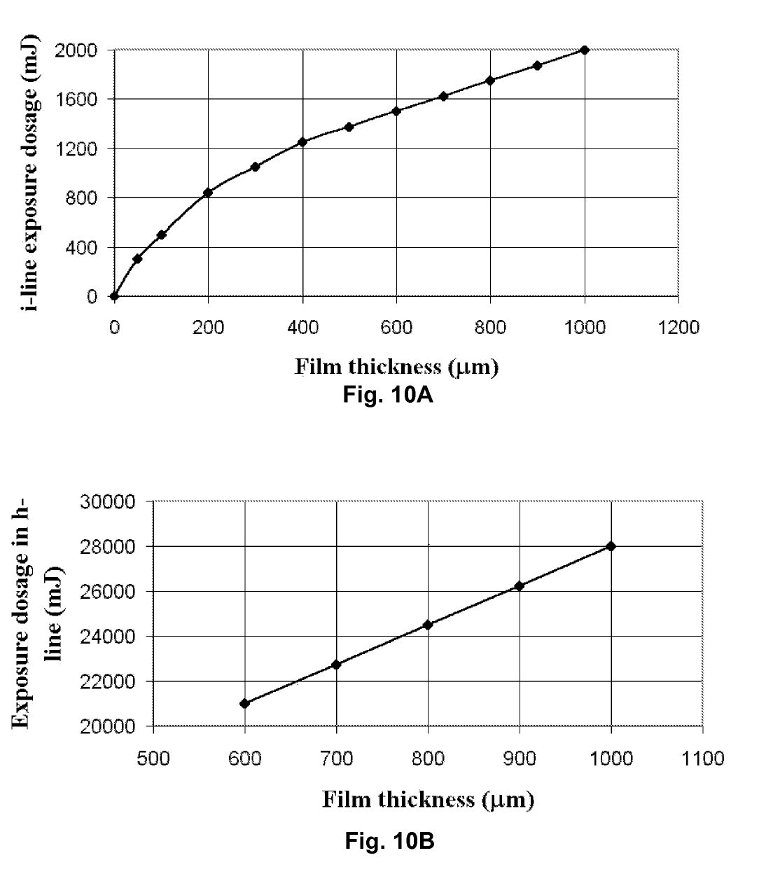

FIGS. 10(A) and (B) depict preferred UV exposure dosages for the i-line and h-line, respectively, for different film thicknesses of the EPON 154/EPON 165 composite photoresist. For photoresist films thinner than 500 μm, a broadband light source can be used, following the recommended exposure dosage shown in FIG. 10(A). When the film thickness is more than 500 μm, the exposure shown in FIG. 10(B) is recommended, using an h-line dominated light source in which the i-line component is eliminated. For example, with a 1:1 EPON 154/EPON 165 composite photoresist, the recommended exposure is 48 J/cm² for an h-line dominated broadband light for a photoresist thickness between 700 μm and 1,000 μm.

The EPON 154/EPON 165 photoresist composite has excellent surface wetting properties, and the spin-coated photoresist films are very flat. Indeed, highly uniform photoresist films can be formed across the entire wafer surface area by simply pouring photoresist solution onto the wafer, without the need for spin-coating. A more viscous solution should be used in the absence of spin-coating.

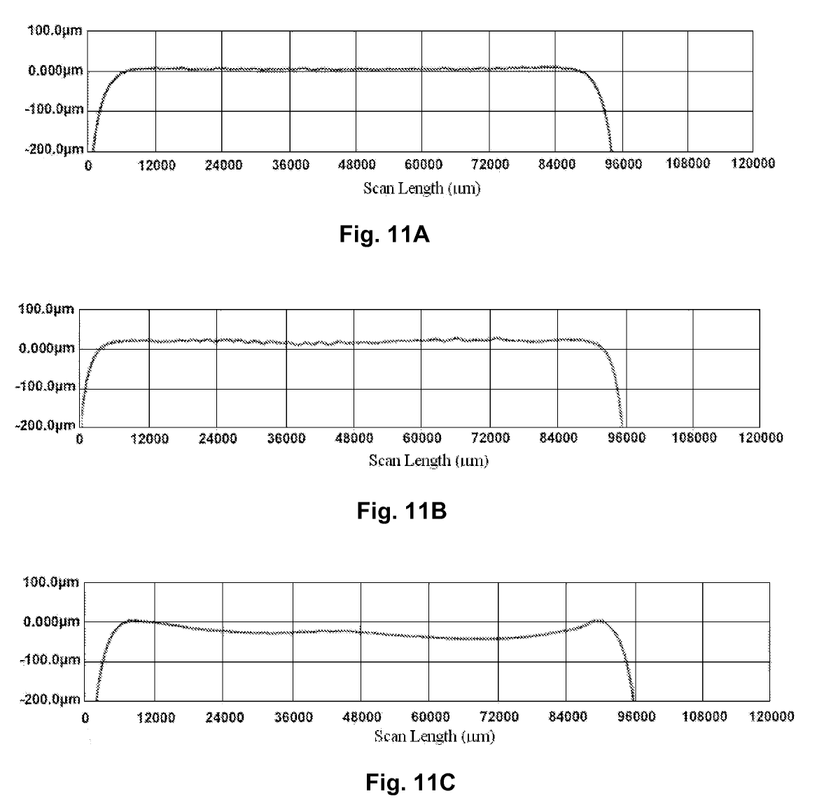

FIGS. 11(A) through (C) show typical surface profiles for the 1:1 composite EPON 154/EPON 165 photoresist, for an SU-8 2100 photoresist, and for an SU-8 100 photoresist; all measured with a Tencor P-2 Long Scan Profiler (KLA-Tencor, San Jose, Calif., USA). All samples were spin-coated and pre-baked. “Total Indicator Run-out” (TIR) was defined as the difference between maximum and minimum profile heights for a section of the plot between measurement cursors. The surface profiles shown in FIGS. 11(A) through (C), taken across a span of 80 mm of each photoresist, corresponded to TIR values of 5.5 μm for the composite EPON 154/EPON 165 photoresist, 17.8 μm for SU-8 2100, and 46.0 μm for an SU-8 100 photoresist. In other words, the EPON 154/EPON 165 composite surface was much flatter than either of the two SU-8 surfaces.

### EXAMPLE 13

### A Preferred Embodiment of a EPON 154/EPON 165 Composite Photoresist

In a preferred embodiment, we prepare a 1:1 mass ratio EPON 154/EPON 165 photoresist mixture in which the total composition comprises (by mass) 80.75% resin, 14.25% GBL, and 5% UVI 6970. A preferred processing procedure is as follows:

1) Spin-coat the photoresist solution on a substrate for 25 seconds at the speed shown in FIG. 8 for the desired film thickness.
2) Soft-bake the photoresist. The temperature is first ramped from 20° C. to 75° C. over 30 minutes, held at 75° C. for 10 minutes, increased to 96-110° C. over 30 minutes, held at 96-110° C. for the time period shown in FIG. 9, ramped down to 75° C. in 30 minutes, and is finally held at 75° C. for 15 minutes. For film thicknesses less than ˜500 μm, the sample is then allowed to cool to room temperature; while thicker films are annealed by cooling to 55° C. over 40 minutes, holding at 55° C. for 4 hours, and then ramped to 20° C. over 3 hours. The pre-exposure baking time can be determined using the baking curve shown in FIG. 9.
3) Expose the photoresist film. For films thinner than ˜500 μm, broadband UV light is preferred. For thicker films (˜500 μm to 1 mm or more), a UV light source with an optimized ratio between h-line and i-line wavelengths is preferred. Our experiments show that a preferred dosage ratio of i-line to h-line wavelengths is ˜1:14. The preferred exposure can be found in FIG. 10. With an ultra-thick resist, it is preferred to use light with lower absorption, to obtain sufficient exposure at the bottom of the resist. Shorter wavelengths tend to be absorbed more at the surface, leading to overexposure at the top and underexposure at the bottom. The h-line promotes straight sidewalls, while the i-line promotes stronger polymerization.
4) Post-bake the exposed sample. The temperature is ramped from 20° C. to 75° C. in 30 minutes, held at 75° C. for 10 minutes, then ramped to 96° C. over 30 minutes, and held at 100° C. for 30 minutes. The sample can then be ramped down to 75° C. over 30 minutes, and held at 75° C. for 15 minutes. At this point, for films less than 500 μm thick, the sample can simply be permitted to cool naturally from 75° C. to room temperature; or, for films thicker than 1 mm, the sample may be annealed by ramping from 75° C. to 55° C. over 40 minutes, held at 55° C. for 4 hours, and finally ramped down to 20° C. over 3 hours.
5) Develop the sample. The exposed photoresist is developed in PGMEA developer, and then rinsed with isopropanol until no milkiness is seen in the developer solution, indicating that development has essentially concluded. The sample is then rinsed with deionized water and air-dried.

### EXAMPLE 14

### Microstructures Manufactured from the EPON 154/EPON 165 Composite Photoresist

We have prepared microstructures using the new EPON 154/EPON 165 composite photoresist. Scanning electron micrographs of the structures showed that the new resist has excellent UV lithography properties. Those photographs are not reproduced here, but may be viewed as FIGS. 14(A)-(D) and 15(A)-(E) of R. Yang et al., “A New UV Lithography Photoresist Based on Composite of EPON Resins 165 and 154 for Fabrication of High-Aspect-Ratio Microstructures,” Sensors and Actuators A, vol. 135 pp. 625-636 (2007), all of which are hereby incorporated by reference. The microstructures depicted in those photographs had heights of 1028 or 1159 μm, excellent side wall qualities, and aspect ratios up to ˜100. These results are superior to what has been reported for SU-8 microstructures. No cracks were seen at the corners, which has been a common problem for cured SU-8 microstructures. In SU-8 microstructures, there is a marked tendency for long, fine lines to de-bond from the substrate. By contrast, we observed no de-bonding with long-line microstructures formed from the novel resist on a Si substrate. By varying the dosage ratio between i-line and h-line, sidewalls with tapered angles can be obtained. By optimizing the dosage ratio between i-line and h-line, excellent vertical sidewalls with sharp edges were obtained. Our experiments on these embodiments found a dosage ratio of i-line to h-line wavelengths of ˜1:14. (Absorption of the h-line is lower than that for the i-line.) No “T-topping” was observed, as is commonly seen in ultra-thick SU-8 UV lithography.

### EXAMPLE 15

### Photo-curable Glue

The disclosed compositions may be used for purposes other than as resists in making MEMS. For example, such a composition may also be used as a photo-curable glue to join metals, polymers, composites, or other materials. The composition may be applied to either or both surfaces to be bonded; the surfaces are then brought into contact, with the composition layer in between; and the glue is then cured by exposure to ultraviolet light or to X-rays. It will often be convenient to use sunlight as the ultraviolet source for such applications.

### MISCELLANEOUS

Unless context clearly indicates otherwise, where the article “a” or “an” is used in the claims below, it should be understood to mean “at least one” or “one or more.” For example, a composition that is said to comprise “a resin” should be understood to comprise “at least one resin” or to comprise “one or more resins.”

The complete disclosures of all references cited in this specification are hereby incorporated by reference, including without limitation the complete disclosure of the priority application, Ser. No. 60/954,195. Also incorporated by reference are the complete disclosures of the following papers and presentations by the inventors, all of which are believed not to be prior art to the present application: R. Yang et al., “A New UV Lithography Photoresist Based on Composite of EPON Resins 165 and 154 for Fabrication of High-Aspect-Ratio Microstructures,” Sensors and Actuators A, vol. 135 pp. 625-636 (2007; available online Oct. 18, 2006); R. Yang, “A New Negative-tone, UV Lithography Photoresist for Fabrication of Ultra-High-Aspect-Ratio Microstructures,” presentation at ASME International Mechanical Engineering Congress and Exposition (Chicago, Ill., Nov. 5-10, 2006); R. Yang et al., “A New UV Lithography Photoresist for Fabrication of High-Aspect-Ratio Microstructures,” presentation at 7th International Workshop on High-Aspect-Ratio Micro-Structure Technology (Besancon, France, Jun. 7-9, 2007); W. Wang, “UV Lithography of SU-8 and A New Negative Tone Resist and the Applications in MEMS,” presentation given at Tsinghua University (Beijing, China, Jun. 16, 2008); W. Wang, “Recent Development of Ultra Thick Resist Lithography and the Applications in MEMS and Microfabrications,” presentation given at China Science and Technologies University (HeFei, China, Jun. 13, 2008). In the event of an otherwise irreconcilable conflict, however, the present specification shall control.

What is claimed:

1. A composition comprising a resin, a solvent, and a photoinitiator; wherein:
(a) the mass of said resin is between about 50% and about 95% of the total mass of said composition; the mass of said solvent is between about 5% and about 50% of the total mass of said composition; and the mass of said photoinitiator is between about 0.05% and about 15% of the total mass of said composition;
(b) at least 5% of said resin by mass is EPON 154, or EPON 165, or a mixture of EPON 154 and EPON 165;
(c) said solvent is present in a concentration that dissolves essentially all of said resin, to form a solution of said resin in said solution; and
(d) said photoinitiator is soluble in said solvent; and either: (i) said photoinitiator is dissolved in said resin solution, or (ii) said photoinitiator and said resin solution are packaged separately within a single kit, so that said photoinitiator and said resin solution may readily be mixed by a user of said kit.

2. A composition as in claim 1, wherein at least 10% of said resin by mass is a mixture of EPON 154 and EPON 165.

3. A composition as in claim 2, wherein the ratio of EPON 154 to EPON 165 by mass is between 5:1 and 1:5.

4. A composition as in claim 3, wherein the ratio of EPON 154 to EPON 165 by mass is between 40:60 and 60:40.

5. A composition as in claim 1, wherein said solvent comprises gamma butyrolactone.

6. A composition as in claim 1, wherein said photoinitiator comprises Cyracure UVI 6970.

7. A method for forming a microstructure on a substrate, using a composition as in claim 1, said method comprising the sequential steps of:
(a) mixing together the photoinitiator and the resin solution, if the photoinitiator and the resin solution have not previously been mixed together;
(b) depositing the resin solution and photoinitiator to form a resist layer on a substrate, and removing the solvent;
(c) selectively exposing portions of the resist layer to ultraviolet light, X-rays, or an electron beam, in a dosage sufficient to cause the photoinitiator to induce polymerization in the exposed portions of the resist;
(d) developing the exposed resist, by selectively dissolving and removing the unexposed portions of the resist layer; and
(e) hard-baking the developed resist, to further polymerized the exposed portions of the resist.

8. A method as in claim 7, wherein said selective exposure step comprises irradiation with collimated X-rays.

9. A method as in claim 7, wherein said selective exposure step comprises irradiation with collimated ultraviolet light.

10. A method as in claim 7, wherein said selective exposure step comprises irradiation with a collimated electron beam.

11. A method as in claim 7, wherein at least 10% of the resin by mass is a mixture of EPON 154 and EPON 165.

12. A method as in claim 11, wherein the ratio of EPON 154 to EPON 165 by mass is between 5:1 and 1:5.

13. A method as in claim 11, wherein the ratio of EPON 154 to EPON 165 by mass is between 40:60 and 60:40.

14. A method as in claim 7, wherein at least one feature in the developed resist has an aspect ratio greater than 100.

15. A method as in claim 7, wherein the thickness of the resist layer is 1000 μm or greater.

16. A method for bonding two surfaces together, using a composition as in claim 1, said method comprising the sequential steps of:
(a) mixing together the photoinitiator and the resin solution, if the photoinitiator and the resin solution have not previously been mixed together;
(b) depositing the resin solution and photoinitiator to form a photoactivatable glue layer on one or both surfaces;
(c) bringing the two surfaces together, with the glue layer between and contacting both surfaces;
(d) exposing the glue layer to ultraviolet light or X-rays, in a dosage sufficient to cause the photoinitiator to induce polymerization in the exposed glue, and to cause the exposed glue to cross-link to both surfaces, and to bond the surfaces to one another.
